(19) United States
(12) Patent Application Publication
(10) Pub. No.: US 2024/0246452 A1
(43) Pub. Date: Jul. 25, 2024

(54) SYSTEMS AND METHODS FOR LITHIUM BATTERY PROGNOSTIC ANALYTICS AND CONDITION MONITORING

(71) Applicant: Honeywell International Inc., Charlotte, NC (US)

(72) Inventors: Tejesh Murthy CHANDRASHEKAR, Bangalore (IN); Savita KALLIHAL, Bangalore (IN)

(21) Appl. No.: 18/185,077

(22) Filed: Mar. 16, 2023

(30) Foreign Application Priority Data
Jan. 23, 2023 (IN) 202311004420

(51) Int. Cl. B60L 58/24; G01R 31/379

(52) U.S. Cl. CPC B60L 58/24; G01R 31/379; B60L 2250/16; B60L 2260/56; G01R 31/367

(57) ABSTRACT

Disclosed are methods and systems for preventing battery failure by identifying battery maintenance actions for a vehicle system. For instance, a method may include receiving at least one thermal image corresponding to at least one battery of at least one vehicle, converting the at least one thermal image into one or more parameters, transmitting the one or more parameters to a condition monitoring system, evaluating the one or more parameters based on one or more conditions to determine that at least one of the one or more parameters meet at least one of the one or more conditions, determining one or more battery maintenance actions based on the at least one of the one or more parameters that meets the at least one of the one or more conditions, and outputting the one or more battery maintenance actions to one or more user interfaces of a user device.

### CROSS-REFERENCE TO RELATED APPLICATION(S)

This application claims the benefit of priority to Indian Provisional Patent application Ser. No. 20/231,1004420, filed Jan. 23, 2023, the entirety of which is incorporated by reference herein.

### TECHNICAL FIELD

Various embodiments of the present disclosure relate generally to methods and systems for preventing battery failure by identifying battery maintenance actions for a vehicle system generally.

### BACKGROUND

Unmanned aerial vehicles (UAV), urban air mobility (UAM), and traditional aircraft vehicles are often used as transportation tools for cargo or passengers. UAVs, UAMs, and traditional aircraft vehicles utilize one or more lithium-ion batteries for power. However, lithium-ion batteries are susceptible to thermal runaway, which may result in the release of gases that can pose hazards. It is desirable to identify battery maintenance actions in order to efficiently and effectively prevent battery failure. Conventional techniques do not provide for the prevention of a battery failure. Instead, conventional techniques may address what to do after the battery fails. Thus, there exists a need to identify battery maintenance actions in order to efficiently and effectively prevent battery failure of UAVs, UAMs, and traditional aircraft vehicles.

This disclosure is directed to addressing above-referenced challenges. The background description provided herein is for the purpose of generally presenting the context of the disclosure. Unless otherwise indicated herein, the materials described in this section are not prior art to the claims in this application and are not admitted to be prior art, or suggestions of the prior art, by inclusion in this section.

### SUMMARY OF THE DISCLOSURE

According to certain aspects of the disclosure, systems and methods are disclosed for preventing battery failure by identifying one or more battery maintenance actions for a vehicle system.

In one aspect, an exemplary embodiment of a computer-implemented method for preventing battery failure by identifying one or more battery maintenance actions for a vehicle system is disclosed. The method may include receiving, by a data acquisition system, at least one thermal image corresponding to at least one battery of at least one vehicle, the at least one thermal image including pixel data. The method may further include converting, by the data acquisition system, the at least one thermal image into one or more parameters, the one or more parameters corresponding to one or more pixels of the pixel data. The method may further include transmitting, by the data acquisition system, the one or more parameters to a condition monitoring system. The method may further include evaluating, by the condition monitoring system, the one or more parameters based on one or more conditions to determine that at least one of the one or more parameters meet at least one of the one or more conditions. The method may further include, based on the evaluating, determining, by the condition monitoring system, one or more battery maintenance actions based on the at least one of the one or more parameters that meets the at least one of the one or more conditions. The method may further include outputting, by the condition monitoring system, the one or more battery maintenance actions to one or more user interfaces of a user device.

In one aspect, a computer system for preventing battery failure by identifying one or more battery maintenance actions for a vehicle system is disclosed. The computer system may include a memory having processor-readable instructions stored therein, and one or more processors configured to access the memory and execute the processor-readable instructions, which when executed by the one or more processors configures the one or more processors to perform a plurality of functions. The functions may include receiving, by a data acquisition system, at least one thermal image corresponding to at least one battery of at least one vehicle, the at least one thermal image including pixel data. The functions may further include converting, by the data acquisition system, the at least one thermal image into one or more parameters, wherein the one or more parameters correspond to one or more pixels of the pixel data. The functions may further include transmitting, by the data acquisition system, the one or more parameters to a condition monitoring system. The functions may further include evaluating, by the condition monitoring system, the one or more parameters based on one or more conditions to determine that at least one of the one or more parameters meet at least one of the one or more conditions. The functions may further include, based on the evaluating, determining, by the condition monitoring system, one or more battery maintenance actions based on the at least one of the one or more parameters that meets the at least one of the one or more conditions. The functions may further include outputting, by the condition monitoring system, the one or more battery maintenance actions to one or more user interfaces of a user device.

In one aspect, a non-transitory computer-readable medium containing instructions for preventing battery failure by identifying one or more battery maintenance actions for a vehicle system is disclosed. The instructions may include receiving, by a data acquisition system, at least one thermal image corresponding to at least one battery of at least one vehicle, the at least one thermal image including pixel data. The instructions may further include converting, by the data acquisition system, the at least one thermal image into one or more parameters, the one or more parameters corresponding to one or more pixels of the pixel data. The instructions may further include transmitting, by the data acquisition system, the one or more parameters to a condition monitoring system. The instructions may further include evaluating, by the condition monitoring system, the one or more parameters based on one or more conditions to determine that at least one of the one or more parameters meet at least one of the one or more conditions. The instructions may further include, based on the evaluating, determining, by the condition monitoring system, one or more battery maintenance actions based on the at least one of the one or more parameters that meets the at least one of the one or more conditions. The instructions may further include outputting, by the condition monitoring system, the one or more battery maintenance actions to one or more user interfaces of a user device.

It is to be understood that both the foregoing general description and the following detailed description are exemplary and explanatory only and are not restrictive of the disclosed embodiments, as claimed.

### BRIEF DESCRIPTION OF THE DRAWINGS

The accompanying drawings, which are incorporated in and constitute a part of this specification, illustrate various exemplary embodiments and together with the description, serve to explain the principles of the disclosed embodiments.

FIG. 1 depicts a schematic diagram illustrating an example environment implementing methods and systems of this disclosure, according to one or more embodiments.

FIG. 2 depicts an architecture diagram illustrating a system and framework for preventing battery failure, according to one or more embodiments.

FIG. 3 depicts a schematic diagram illustrating heat transfer in a battery, according to one or more embodiments.

FIG. 4 depicts a three-dimensional diagram illustrating a ground station thermal imaging camera(s), according to one or more embodiments.

FIG. 5 depicts a flowchart of an exemplary method for preventing battery failure by identifying one or more battery maintenance actions for a vehicle system, according to one or more embodiments.

FIG. 6 depicts an example system that may execute techniques presented herein.

### DETAILED DESCRIPTION OF EMBODIMENTS

According to certain aspects of the disclosure, methods and systems are disclosed for preventing battery failure by identifying one or more battery maintenance actions for a vehicle system. Conventional techniques may not be suitable at least because conventional techniques, among other things, do not provide for the prevention of a battery failure. Additionally, conventional techniques may not include the ability to utilize a machine-learning model to increase the efficiency and accuracy of the system. Accordingly, improvements in technology relating to preventing battery failure by identifying one or more battery maintenance actions for a vehicle system are needed.

Unmanned aerial vehicles (UAV), urban air mobility (UAM), and traditional aircraft are often used as transportation tools for cargo or passengers. UAVs, UAMs, and traditional aircraft may utilize one or more lithium-ion batteries for power. However, lithium-ion batteries are susceptible to thermal runaway, which may result in the release of gases that can pose hazards. Additionally, the electrochemical performance of a lithium-ion battery may be strongly affected by the temperature of the battery. For example, during the charge and discharge cycles, the lithium-ion battery may be subjected to an increment of temperature that may accelerate the aging and/or loss of efficiency of the lithium-ion battery. The thermal failure in lithium-ion batteries may lead to equipment failures in UAVs, UAMs, and traditional aircraft, such as leading to the downtime of the vehicles. As a result, there exists a need to identify battery maintenance actions in order to efficiently and effectively prevent battery failure of UAVs, UAMs, and traditional aircraft vehicles.

Advantages of such a system may include the ability to extend the lifetime of the batteries, as well as prevent and anticipate battery failure. Additional advantages may include a system that is agnostic towards the battery placement. For example, irrespective of battery placement in the aircraft, the thermal imaging camera may have the capability to detect the battery's radiation. Additional advantages may include the ability to capture thermal images of multiple batteries, without encountering conflicts in monitoring and prediction. Additional advantages may include increased efficiency and accuracy by using one or more artificial intelligence (AI) models/algorithms.

The systems and methods disclosed herein relate to preventing battery failure by identifying one or more battery maintenance actions for a vehicle system. The systems and methods may include receiving, by a data acquisition system, at least one thermal image corresponding to at least one battery of at least one vehicle, the at least one thermal image including pixel data. The systems and methods may further include converting, by the data acquisition system, the at least one thermal image into one or more parameters, the one or more parameters corresponding to one or more pixels of the pixel data. The systems and methods may further include transmitting, by the data acquisition system, the one or more parameters to a condition monitoring system. The systems and methods may further include evaluating, by the condition monitoring system, the one or more parameters based on one or more conditions to determine that at least one of the one or more parameters meet at least one of the one or more conditions. The systems and methods may further include, based on the evaluating, determining, by the condition monitoring system, one or more battery maintenance actions based on the at least one of the one or more parameters that meets the at least one of the one or more conditions. The systems and methods may further include, outputting, by the condition monitoring system, the one or more battery maintenance actions to one or more user interfaces of a user device.

The terminology used below may be interpreted in its broadest reasonable manner, even though it is being used in conjunction with a detailed description of certain specific examples of the present disclosure. Indeed, certain terms may even be emphasized below; however, any terminology intended to be interpreted in any restricted manner will be overtly and specifically defined as such in this Detailed Description section. Both the foregoing general description and the following detailed description are exemplary and explanatory only and are not restrictive of the features, as claimed.

As used herein, the terms “comprises,” “comprising,” “having,” including,” or other variations thereof, are intended to cover a non-exclusive inclusion such that a process, method, article, or apparatus that comprises a list of elements does not include only those elements, but may include other elements not expressly listed or inherent to such a process, method, article, or apparatus. In this disclosure, relative terms, such as, for example, “about,” “substantially,” “generally,” and “approximately” are used to indicate a possible variation of ±10% in a stated value. The term “exemplary” is used in the sense of “example” rather than “ideal.” As used herein, the singular forms “a,” “an,” and “the” include plural reference unless the context dictates otherwise.

While the embodiments in this disclosure are directed towards batteries, such embodiments are not meant to be limiting. The systems and methods may be applied to many different components of a vehicle, such as vehicle wheels, wings, engines, and the like. Moreover, while the embodiments in this disclosure are directed towards aircraft vehicles, such embodiments are not meant to be limiting. The systems and methods may be applied to many different types of vehicles, such as electric vehicles, cars, trucks, boats, trains, and the like.

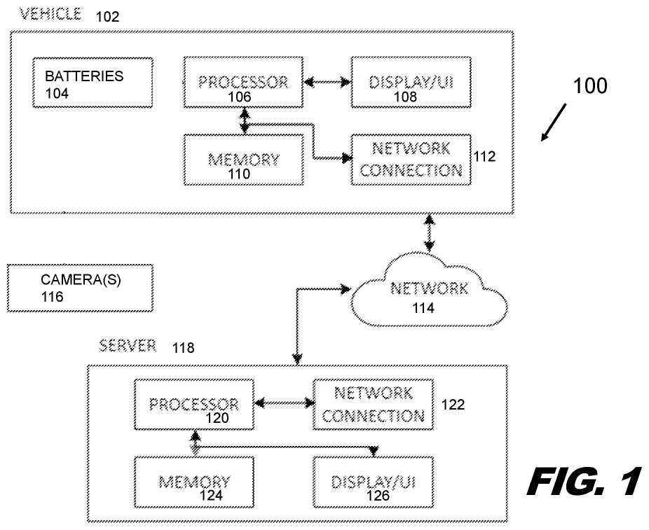

FIG. 1 depicts an example of a system environment 100 in which systems, methods, and other aspects of the present disclosure may be implemented. The system environment 100 of FIG. 1 may include a vehicle 102, a network 114, and server 118. In some embodiments, the system environment 100 may further include camera(s) 116. Vehicle 102 may include one or more batteries 104 and processor 106 that may be in communication with a plurality of other components such as memory 110, display/user interface (UI) 108, and network connection 112. Processor 106 may include one or more processors that comprise the computing and flight management systems of vehicle 102.

Memory 110 may be one or more components configured to store data related to vehicle 102, including instructions for operating flight components and vehicle systems (e.g., autopilot, route planning, communication). Processor 106 and memory 110 may display information to, and receive inputs from an operator of vehicle 102 via display/UI 108. Display/UI 108 may be of any suitable type, such as one or more monitors, touchscreen panels, heads-up displays, and may include operator input devices such as joysticks, buttons, touch-responsive panels, mice, trackpads, voice recognition devices, and the like. As the vehicle 102 operates, processor 106 may generate one or more graphical user interfaces (GUIs) for display on display/UI 108, to provide relevant and useful information to operators and/or passengers of vehicle 102. Additionally, as the vehicle 102 operates, the one or more batteries 104 may provide power to one or more components of vehicle 102. The one or more batteries 104 may include lithium-ion batteries.

Vehicle 102 may use network connection 112 to communicate with other elements of the system environment, for example, via network 120 or directly by radio communication. Network 114 may be implemented as, for example, the internet, a wireless network, Bluetooth, Near Field Communication (NFC), or any other type of network or combination of networks that provides communications between one or more components of the system environment 100. In some embodiments, the network 114 may be implemented using a suitable communication protocol or combination of protocols such as a wired or wireless internet connection in combination with a cellular data network.

One or more servers 118 may be repositories for system information such as map data, building data, flight plan data, and the like. Server 118 may include a processor 120, a network connection 122, a memory 124, and a display/UI 126. Memory 124 may store data, processor 120 may access and organize the stored data to respond to requests and provide updates to the stored data, and information may be provided to other elements in system environment 100 via network connection 122. Display/UI 126 may be of any suitable type, such as one or more monitors, touchscreen panels, heads-up displays, and may include operator input devices such as joysticks, buttons, touch-responsive panels, mice, trackpads, voice recognition devices, and the like. In some embodiments, server 118 may communicate directly with vehicle 102 via network 114.

One or more camera(s) 116 may include infrared or optical cameras, LIDAR, dual capability, or other visual imaging systems to capture imaging data, such as thermal data, of the one or more batteries 104 of the vehicle 102. The camera(s) 104 may obtain infrared images; optical images; and/or LIDAR point cloud data, or any combination thereof (collectively “imaging data”). The camera(s) 104 may transmit the imaging data and/or the machine vision outputs of the machine vision function to the vehicle 102 and/or network 114. Without deviating from the scope of this disclosure, vehicle 102 may have additional elements that can be in communication with processor 106.

In the following methods, various acts may be described as performed or executed by a component from FIG. 1. However, it should be understood that in various embodiments, various components of the system environment 100 discussed herein may execute instructions or perform acts including the acts discussed herein. An act performed by a device may be considered to be performed by a processor, actuator, or the like associated with that device. Further, it should be understood that in various embodiments, various steps may be added, omitted, and/or rearranged in any suitable manner.

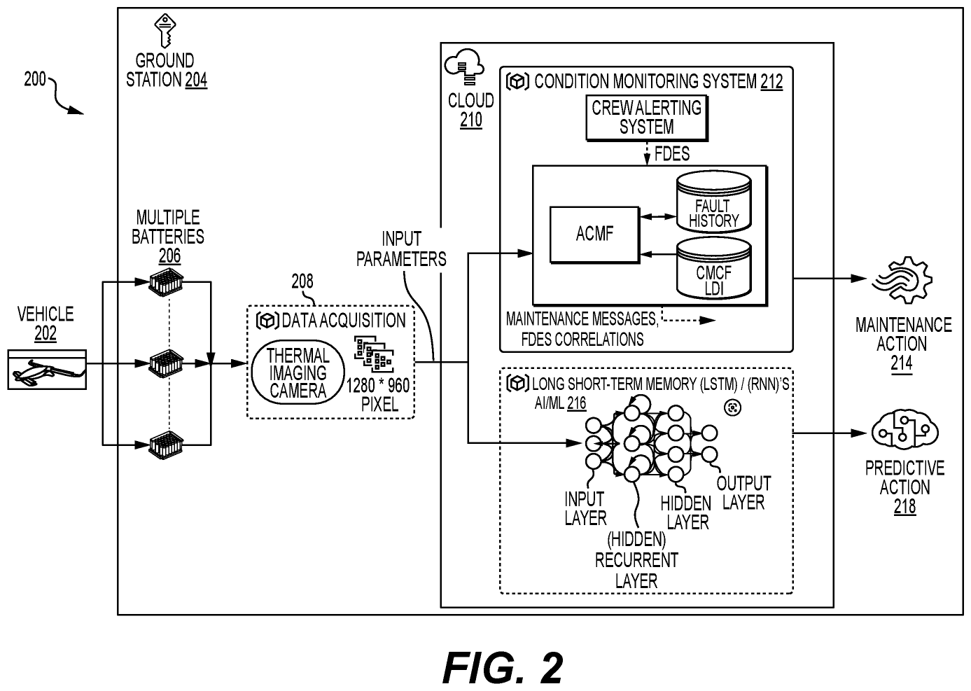

FIG. 2 is a flowchart illustrating a method 200 for preventing battery failure, according to one or more embodiments. Exemplary method 200 may be executed on one or more components of FIG. 1.

Vehicle 202 may include multiple batteries 206. For example, the multiple batteries 206 may include lithium-ion batteries. Additionally, vehicle 202 may include at least one of a UAV, UAM, or a traditional aircraft.

The data acquisition system 208 may be installed in one or more ground stations 204. Data acquisition system 208 may include a thermal imaging camera that may capture one or more thermal images of the multiple batteries 206. For example, the data acquisition system 208, which is a part of ground station 204, may capture thermal images of the multiple batteries 206 during charge cycles and/or discharge cycles. The charge cycles of the multiple batteries 206 may include when the vehicle 202 is charging on the one or more ground stations 204. The discharge cycles of the multiple batteries 206 may include landing and/or take-off of the vehicle 202 on the ground station. The captured thermal images may be in the form of pixel data. For example, the thermal images may be captured in a 1280 * 960 pixel format. Data acquisition system 208 may then convert the one or more thermal images into one or more parameters, where the one or more parameters may correspond to one or more pixels.

Data acquisition system 208 may transmit the one or more parameters to the cloud 210. Specifically, data acquisition system 208 may transmit the one or more parameters to a conditioning monitoring system 212 and/or a long short-term memory (LSTM) 216 that run on cloud 210. The cloud 210 including the conditioning monitoring system 212 and/or the long short-term memory (LSTM) 216 results in the removal of boundaries on the number of parameters to process.

The condition monitoring system 212 may include an airplane conditioning monitoring function (ACMF) that may communicate with one or more databases that may store a fault history and/or aircraft configuration data (CMCF LDI). The ACMF may also be in communication with a crew alerting system. The crew alerting system may include an aircraft system that monitors aircraft and provides alerts to users regarding system failures. For example, the crew alerting system may provide one or more CAS messages to the users. Additionally, or alternatively, the crew alerting system may record a FDE in at least one pilot flight log. The CAS messages and/or the FDE may be used as input to the condition monitoring system 212. The condition monitoring system 212 may sample/monitor the one or more parameters from the data acquisition system 208. The condition monitoring system 212 may also evaluate conditions based on user-specified/OEM specified conditions and combinations defined in the aircraft configuration data and/or fault models. The aircraft configuration data may include configuration information of different vehicles (e.g., aircrafts). The configuration information may be used to configure the condition monitoring system 212, based on the configuration processing of input data. The fault models may include definitions of multiple trigger events. The condition monitoring system 212 may be configured by utilizing one or more fault applications. For example, the condition monitoring system 212 may begin to monitor input data/parameters, where trigger events may be triggered by one or more trigger conditions. Additionally, the trigger events may correspond to one or more maintenance messages/actions that may be displayed to one or more users. Additionally, when user/OEM specified conditions are met, the ACMF may trigger a maintenance message 214. For example, a parameter may include a pixel value that may indicate the temperature of the battery. Additionally, a pixel value between 0 and 270 may indicate that the battery cell is within a cooling limit range. The pixel value exceeding the cooling limit range may indicate that the battery cell is starting to generate heat. The maintenance message 214 may notify one or more users that a particular maintenance action is needed. For example, the particular maintenance action may indicate that a battery may need to be replaced or charged. The maintenance action may also inform one or more users about a heat exchange between battery cells, the surface, and/or the surrounding environment.

The LSTM 216 may process the one or more parameters using one or more AI models/algorithms to predict one or more next pixel state values. The next pixel state value may indicate the predicted temperature/health of the particular battery cell. The one or more parameters may include pixel data, such as one or more pixels. The LSTM 216 may be executed on cloud 210, so that the processed one or more parameters may be saved as historical data on cloud 210 for future use (e.g., by the AI models/algorithms). Additionally, each time the UAM/UAS vehicle lands on the ground station 204, one or more thermal images may be captured of the multiple batteries 206, and the corresponding pixel values may be processed by the LSTM 216 to predict the next pixel state values. The LSTM 216 may use a previous iteration pixel value and/or a current iteration pixel value when processing the one or more parameters. For example, multiple iteration pixel values may be captured, recorded, and used to train the AI models/algorithms to predict the next pixel state value. Upon predicting the next pixel state value, the LSTM 216 may determine one or more predictive actions 218. The LSTM may also estimate the remaining useful life of the one or more batteries and/or the time-to-failure/downtime of the one or more batteries. The one or more predictive actions 218 may include one or more notifications that indicate actions that a user may take to prevent a maintenance issue. For example, the next pixel state value may indicate that one or more batteries are close to overheating. As a result, one or more predictive actions may include notifying a user that such batteries should be replaced to prevent the overheating.

In some embodiments, the LSTM (RNN) 216 may include an input layer, a (hidden) recurrent layer, one or more hidden layers, and/or an output layer. The LSTM (RNN) 216 may include a robust network that may have a memory of prior inputs. The

RNN may take several prior inputs and extrapolate the inputs with improved accuracy. Additionally, the RNN may consider what has been learned from prior inputs to classify the current input. The RNN may classify the current input with the assistance of fully connected one or more layers. The LSTM (RNN) 216 may include a feedback mechanism at the recurrent layer. For example, the arrows feeding back into the nodes of the hidden layer may also be classified as the recurrent layer of the neural network.

Although FIG. 2 shows example blocks of exemplary method 200, in some implementations, the exemplary method 200 may include additional blocks, fewer blocks, different blocks, or differently arranged blocks than those depicted in FIG. 2. Additionally, or alternatively, two or more of the blocks of the exemplary method 200 may be performed in parallel.

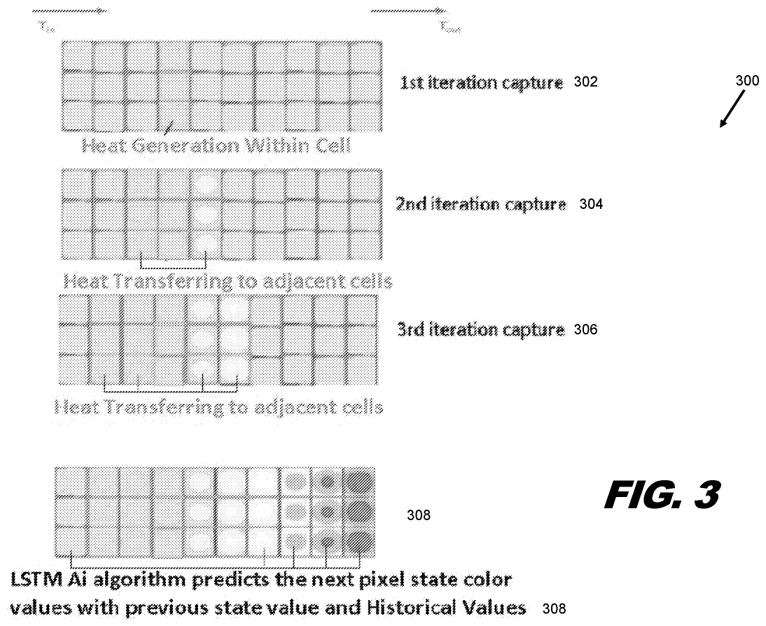

FIG. 3 illustrates a diagram 300 for capturing and processing of three iterations of pixel values and predicting the fourth iteration of pixel values, according to one or more embodiments. In some embodiments, the transferring of heat may be illustrated by a pixel state color value. For example, the color green may indicate low heat, whereas the color red may indicate high heat that may be indicative of overheating. The first iteration capture 302 may indicate heat generation within a cell. The second iteration capture 304 may indicate the heat transferring from the cell to adjacent cells. The third iteration capture 306 may indicate the heat transferring from the adjacent cells to additional adjacent cells. The LSTM AI algorithm may predict the next pixel state color values based on one or more previous state values and/or one or more historical values 308.

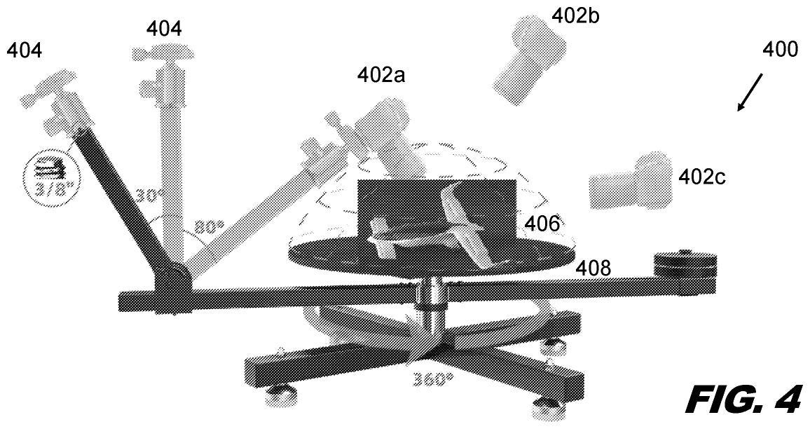

FIG. 4 illustrates a diagram 400 of a ground station thermal imaging camera(s) scanning a vehicle, according to one or more embodiments. The vehicle 406 may land and/or take-off from a ground station 408. The ground station 408 may include one or more cameras 402a, 402b, 402c that may be positioned on one or more camera stands 404. The camera stands may be stationary or may be mobile. For example, the camera stand(s) 404 may be configured to move in 360 degrees around vehicle 406, so that the attached cameras 402a, 402b, and/or 402c may capture all angles of the vehicle 406. Additionally, or alternatively, the camera stand(s) 404 may be configured to move in multiple angles away and/or towards the vehicle 406. In some embodiments, ground station 408 may include a mobile platform. Vehicle 406 may land on the mobile platform, where the mobile platform may be configured to rotate vehicle 406. As vehicle 406 rotates, cameras 402a, 402b, and/or 402c may capture one or more thermal images of vehicle 406.

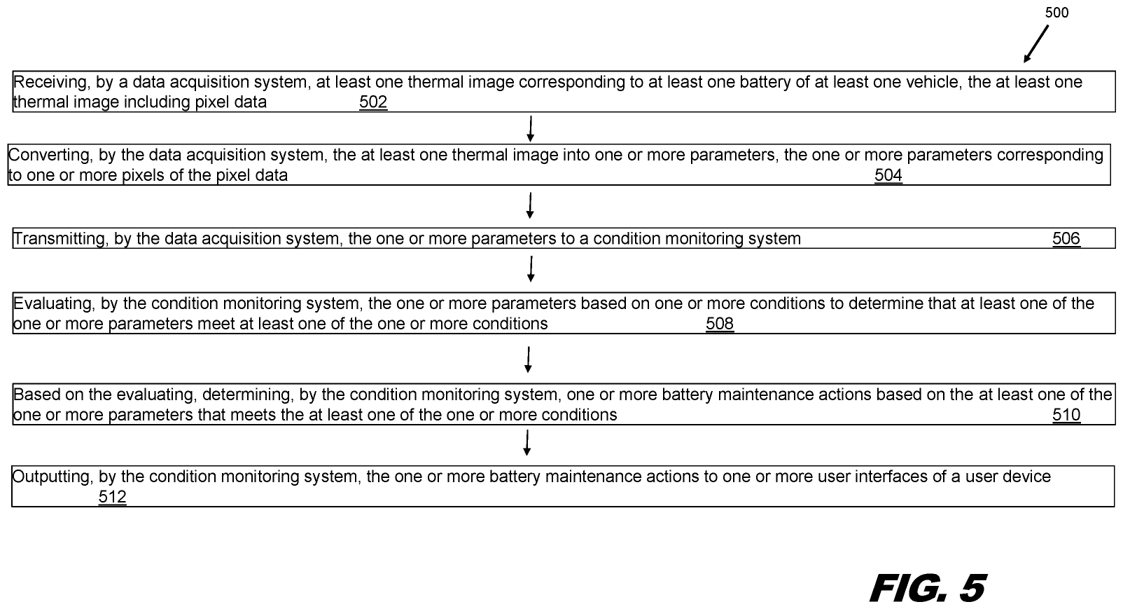

FIG. 5 illustrates an exemplary method 500 for preventing battery failure by identifying one or more battery maintenance actions for a vehicle system, according to one or more embodiments. Notably, method 500 may be performed by one or more processors of a server that is in communication with one or more user devices and other external system(s) via a network. However, it should be noted that method 500 may be performed by any one or more of the server, one or more user devices, or other external systems. Exemplary method 500 may be executed on one or more components of FIGS. 1-4.

The method may include receiving, by a data acquisition system, at least one thermal image corresponding to at least one battery of at least one vehicle, the at least one thermal image including pixel data (Step 502). The at least one vehicle may correspond to at least one aircraft. The vehicle may include the at least one battery, where the at least one battery may include a lithium battery. The at least one thermal image may have been captured by one or more cameras of the data acquisition system. In some embodiments, the one or more cameras may include one or more dual capability cameras. The dual capability cameras may offer a combination of conventional and thermal technology. For example, dual capability cameras may be used in a wide range of thermal detection and surveillance. Additionally, the at least one thermal image may capture some or all of a battery of the vehicle at a point in time. For example, the at least one thermal image may include pixel data of the at least one battery. The pixel data may include information, such as one or more pixel values, corresponding to one or more pixels in the at least one thermal image. In some embodiments, the at least one thermal image may have been captured when the vehicle is on the ground. In some embodiments, the at least one thermal image may have been captured while the vehicle is in flight. In some embodiments, the at least one thermal image may have been captured while the vehicle was in a charge/discharge cycle.

In some embodiments, the method may include capturing, by the data acquisition system, the at least one thermal image during a charge cycle of the at least one battery or a discharge cycle of the at least one battery. For example, the data acquisition system may receive a notification that the battery is in a charge cycle or a discharge cycle. Upon receiving the notification, the data acquisition system may communicate with one or more cameras to capture at least one thermal image corresponding to the battery.

The method may include converting, by the data acquisition system, the at least one thermal image into one or more parameters, the one or more parameters corresponding to one or more pixels of the pixel data (Step 504). The one or more parameters may include one or more temperature parameters. For example, the one or more temperature parameters may indicate a particular temperature for the one or more pixel values. For example, a thermal imaging camber with a 640 x 480 resolution may be equal to 307,200 pixels. Each pixel may include a temperature, where a higher pixel value may be correlated with a temperature and vice versa.

The method may include transmitting, by the data acquisition system, the one or more parameters to a condition monitoring system (Step 506). The condition monitoring system may include at least one of: a vehicle condition monitoring function module, vehicle configuration data, or one or more fault models. The vehicle condition monitoring module may evaluate the one or more parameters based on one or more user-specified/system specified conditions and combinations defined by the vehicle configuration data and/or the one or more fault models.

The method may include evaluating, by the condition monitoring system, the one or more parameters based on one or more conditions to determine that at least one of the one or more parameters meet at least one of the one or more conditions (Step 508). The one or more conditions may be defined based on at least one of: one or more pre-defined fault models or one or more pre-defined boundary conditions. For example, the LDI and fault models may contain pre-defined user-specified and/or OEM-specified trigger conditions and combinations. Alerts (e.g., maintenance messages) may be activated when trigger conditions are met. For example, a pixel value between 0 to 270 may indicate that the pixel is within a cooling limit range. The pixel value exceeding the range may indicate that the battery cell started generating heat (e.g., a trigger condition has been met and a related maintenance message has been set).

The method may include, based on the evaluating, determining, by the condition monitoring system, one or more battery maintenance actions based on the at least one of the one or more parameters that meets the at least one of the one or more conditions (Step 510). The one or more battery maintenance actions may include a battery condition or an indication of whether the at least one battery should be replaced. For example, if the temperature value of at least one of the parameters indicates that the battery is close to a thermal failure, the battery maintenance action may indicate that the battery should be replaced.

The method may include outputting, by the condition monitoring system, the one or more battery maintenance actions to one or more user interfaces of a user device (Step 512). The outputting may include displaying one or more notifications on the one or more user interfaces of the user device. Additionally, the one or more notifications may include the one or more battery maintenance actions. The one or more user interfaces may include one or more interactive user interfaces, where the user may be able to interact with the one or more notifications to indicate that the one or more battery maintenance actions have been addressed.

In some embodiments, the method may include transmitting, by the data acquisition system, the one or more parameters to a prognostic analytics system (e.g., a LSTM). The method may further include predicting, by the prognostic analytics system, one or more predicted pixel state values utilizing a machine-learning algorithm (e.g., AI model/algorithm) based on the one or more parameters and one or more previous pixel states. For example, the machine-learning algorithm may predict a next pixel state value based on a previous pixel value and a present state pixel value. In some embodiments, each time a vehicle lands on a ground station, a thermal image may be captured and the pixel value may be processed to predict the next pixel state value. Additionally, multiple iteration pixel values may be captured, recorded, and used to train the machine-learning algorithm to predict the next pixel state value and a predictive action for the user. For example, the machine-learning algorithm may utilize a trained machine-learning model. The machine-learning model may have been previously trained to use one or more previous parameters and one or more previous pixel states to predict one or more pixel state values. The method may further include storing, by the prognostic analytics system, the one or more predicted pixel state values in one or more data stores. For example, the one or more predicted pixel state values may be stored in one or more data stores in the cloud, ground station, and/or the LSTM.

In some embodiments, the method may further include determining, by the prognostic analytics system, one or more battery predictive actions based on the one or more predicted pixel state values. For example, the battery predictive action may indicate the battery's remaining useful life or a time-to-failure/downtime. Additionally, exemplary battery predictive actions may include a remaining useful life (RUL) prediction, a power degradation curve, and/or a state of health (SOH). The battery predictive action may include an estimated battery replacement date and/or time. The method may further include outputting, by the condition monitoring system, the one or more battery predictive actions to the one or more user interfaces of the user device. The outputting may include displaying one or more battery predictive actions on the one or more user interfaces of the user device. The one or more user interfaces may include one or more interactive user interfaces, where the user may be able to interact with the one or more battery predictive actions to indicate that the one or more battery predictive actions have been addressed.

Although FIG. 5 shows example blocks of exemplary method 500, in some implementations, the exemplary method 500 may include additional blocks, fewer blocks, different blocks, or differently arranged blocks than those depicted in FIG. 5 Additionally, or alternatively, two or more of the blocks of the exemplary method 500 may be performed in parallel.

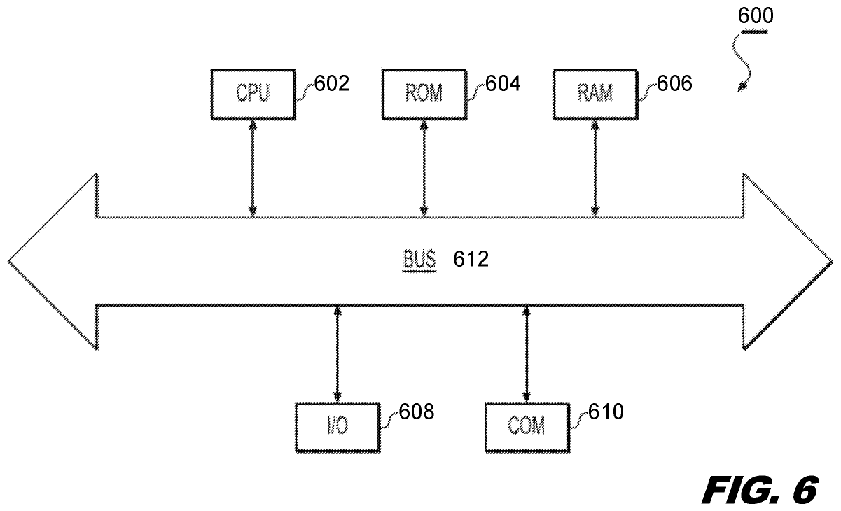

FIG. 6 is a simplified functional block diagram of a computer 600 that may be configured as a device for executing the methods of FIGS. 2 and 5, according to exemplary embodiments of the present disclosure. For example, device 600 may include a central processing unit (CPU) 602. CPU 602 may be any type of processor device including, for example, any type of special purpose or a general-purpose microprocessor device. As will be appreciated by persons skilled in the relevant art, CPU 602 also may be a single processor in a multi-core/multiprocessor system, such system operating alone, or in a cluster of computing devices operating in a cluster or server farm. CPU 602 may be connected to a data communication infrastructure 612, for example, a bus, message queue, network, or multi-core message-passing scheme.

Device 600 also may include a main memory 606, for example, random access memory (RAM), and also may include a secondary memory 604. Secondary memory 604, e.g., a read-only memory (ROM), may be, for example, a hard disk drive or a removable storage drive. Such a removable storage drive may comprise, for example, a floppy disk drive, a magnetic tape drive, an optical disk drive, a flash memory, or the like. The removable storage drive in this example reads from and/or writes to a removable storage unit in a well-known manner. The removable storage unit may comprise a floppy disk, magnetic tape, optical disk, etc., which is read by and written to by the removable storage drive. As will be appreciated by persons skilled in the relevant art, such a removable storage unit generally includes a computer usable storage medium having stored therein computer software and/or data.

In alternative implementations, secondary memory 604 may include other similar means for allowing computer programs or other instructions to be loaded into device 600. Examples of such means may include a program cartridge and cartridge interface (such as that found in video game devices), a removable memory chip (such as an EPROM, or PROM) and associated socket, and other removable storage units and interfaces, which allow software and data to be transferred from a removable storage unit to device 600.

Device 600 also may include a communications interface (“COM”) 610. Communications interface 610 allows software and data to be transferred between device 600 and external devices. Communications interface 610 may include a modem, a network interface (such as an Ethernet card), a communications port, a PCMCIA slot and card, or the like. Software and data transferred via communications interface 610 may be in the form of signals, which may be electronic, electromagnetic, optical, or other signals capable of being received by communications interface 610. These signals may be provided to communications interface 610 via a communications path of device 600, which may be implemented using, for example, wire or cable, fiber optics, a phone line, a cellular phone link, an RF link or other communications channels.

The hardware elements, operating systems and programming languages of such equipment are conventional in nature, and it is presumed that those skilled in the art are adequately familiar therewith. Device 600 also may include input and output ports 608 to connect with input and output devices such as keyboards, mice, touchscreens, monitors, displays, etc. Of course, the various server functions may be implemented in a distributed fashion on a number of similar platforms, to distribute the processing load. Alternatively, the servers may be implemented by appropriate programming of one computer hardware platform.

Program aspects of the technology may be thought of as “products” or “articles of manufacture” typically in the form of executable code and/or associated data that is carried on or embodied in a type of machine-readable medium. “Storage” type media include any or all of the tangible memory of the computers, processors or the like, or associated modules thereof, such as various semiconductor memories, tape drives, disk drives and the like, which may provide non-transitory storage at any time for the software programming. All or portions of the software may at times be communicated through the Internet or various other telecommunication networks. Such communications, for example, may enable loading of the software from one computer or processor into another, for example, from a management server or host computer of the mobile communication network into the computer platform of a server and/or from a server to the mobile device. Thus, another type of media that may bear the software elements includes optical, electrical and electromagnetic waves, such as those used across physical interfaces between local devices, through wired and optical landline networks and over various air-links. The physical elements that carry such waves, such as wired or wireless links, optical links, or the like, also may be considered as media bearing the software. As used herein, unless restricted to non-transitory, tangible “storage” media, terms such as computer or machine “readable medium” refer to any medium that participates in providing instructions to a processor for execution.

Reference to any particular activity is provided in this disclosure only for convenience and not intended to limit the disclosure. A person of ordinary skill in the art would recognize that the concepts underlying the disclosed devices and methods may be utilized in any suitable activity. The disclosure may be understood with reference to the following description and the appended drawings, wherein like elements are referred to with the same reference numerals.

It should be appreciated that in the above description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the Detailed Description are hereby expressly incorporated into this Detailed Description, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those skilled in the art. For example, in the following claims, any of the claimed embodiments can be used in any combination.

Thus, while certain embodiments have been described, those skilled in the art will recognize that other and further modifications may be made thereto without departing from the spirit of the invention, and it is intended to claim all such changes and modifications as falling within the scope of the invention. For example, functionality may be added or deleted from the block diagrams and operations may be interchanged among functional blocks. Steps may be added or deleted to methods described within the scope of the present invention.

The above disclosed subject matter is to be considered illustrative, and not restrictive, and the appended claims are intended to cover all such modifications, enhancements, and other implementations, which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description. While various implementations of the disclosure have been described, it will be apparent to those of ordinary skill in the art that many more implementations are possible within the scope of the disclosure. Accordingly, the disclosure is not to be restricted except in light of the attached claims and their equivalents.

What is claimed is:

1. A computer-implemented method for preventing battery failure by identifying one or more battery maintenance actions for a vehicle system, the method comprising:
receiving, by a data acquisition system, at least one thermal image corresponding to at least one battery of at least one vehicle, the at least one thermal image including pixel data;
converting, by the data acquisition system, the at least one thermal image into one or more parameters, the one or more parameters corresponding to one or more pixels of the pixel data;
transmitting, by the data acquisition system, the one or more parameters to a condition monitoring system;
evaluating, by the condition monitoring system, the one or more parameters based on one or more conditions to determine that at least one of the one or more parameters meet at least one of the one or more conditions;
based on the evaluating, determining, by the condition monitoring system, one or more battery maintenance actions based on the at least one of the one or more parameters that meets the at least one of the one or more conditions; and
outputting, by the condition monitoring system, the one or more battery maintenance actions to one or more user interfaces of a user device.

2. The computer-implemented method of claim 1, the method further comprising:
transmitting, by the data acquisition system, the one or more parameters to a prognostic analytics system;
predicting, by the prognostic analytics system, one or more predicted pixel state values utilizing a machine-learning algorithm based on the one or more parameters and one or more previous pixel states; and
storing, by the prognostic analytics system, the one or more predicted pixel state values in one or more data stores.

3. The computer-implemented method of claim 2, the method further comprising:
determining, by the prognostic analytics system, one or more battery predictive actions based on the one or more predicted pixel state values; and
outputting, by the condition monitoring system, the one or more battery predictive actions to the one or more user interfaces of the user device.

4. The computer-implemented method of claim 1, wherein the at least one battery is a lithium battery.

5. The computer-implemented method of claim 1, the method further comprising:
capturing, by the data acquisition system, the at least one thermal image during a charge cycle of the at least one battery or a discharge cycle of the at least one battery.

6. The computer-implemented method of claim 1, wherein the condition monitoring system includes at least one of: a vehicle condition monitoring function module, vehicle configuration data, or one or more fault models.

7. The computer-implemented method of claim 1, wherein the one or more parameters includes one or more temperature parameters.

8. The computer-implemented method of claim 1, wherein the one or more battery maintenance actions include a battery condition or an indication of whether the at least one battery should be replaced.

9. The computer-implemented method of claim 1, wherein the one or more conditions are defined based on at least one of: one or more pre-defined fault models or one or more pre-defined boundary conditions.

10. A computer system for preventing battery failure by identifying one or more battery maintenance actions for a vehicle system, the computer system comprising:
a memory having processor-readable instructions stored therein; and
one or more processors configured to access the memory and execute the processor-readable instructions, which when executed by the one or more processors configures the one or more processors to perform a plurality of functions, including functions for:
receiving, by a data acquisition system, at least one thermal image corresponding to at least one battery of at least one vehicle, the at least one thermal image including pixel data;
converting, by the data acquisition system, the at least one thermal image into one or more parameters, wherein the one or more parameters correspond to one or more pixels of the pixel data;
transmitting, by the data acquisition system, the one or more parameters to a condition monitoring system;
evaluating, by the condition monitoring system, the one or more parameters based on one or more conditions to determine that at least one of the one or more parameters meet at least one of the one or more conditions;
based on the evaluating, determining, by the condition monitoring system, one or more battery maintenance actions based on the at least one of the one or more parameters that meets the at least one of the one or more conditions; and
outputting, by the condition monitoring system, the one or more battery maintenance actions to one or more user interfaces of a user device.

11. The computer system of claim 10, the functions further comprising:
transmitting, by the data acquisition system, the one or more parameters to a prognostic analytics system;
predicting, by the prognostic analytics system, one or more predicted pixel state values utilizing a machine-learning algorithm based on the one or more parameters and one or more previous pixel states; and
storing, by the prognostic analytics system, the one or more predicted pixel state values in one or more data stores.

12. The computer system of claim 11, the functions further comprising:
determining, by the prognostic analytics system, one or more battery predictive actions based on the one or more predicted pixel state values; and
outputting, by the condition monitoring system, the one or more battery predictive actions to the one or more user interfaces of the user device.

13. The computer system of claim 10, wherein the at least one battery is a lithium battery.

14. The computer system of claim 10, the functions further comprising:
capturing, by the data acquisition system, the at least one thermal image during a charge cycle of the at least one battery or a discharge cycle of the at least one battery.

15. The computer system of claim 10, wherein the condition monitoring system includes at least one of: a vehicle condition monitoring function module, vehicle configuration data, or one or more fault models.

16. The computer system of claim 10, wherein the one or more battery maintenance actions include a battery condition or an indication of whether the at least one battery should be replaced.

17. A non-transitory computer-readable medium containing instructions for preventing battery failure by identifying one or more battery maintenance actions for a vehicle system, the instructions comprising:
receiving, by a data acquisition system, at least one thermal image corresponding to at least one battery of at least one vehicle, the at least one thermal image including pixel data;
converting, by the data acquisition system, the at least one thermal image into one or more parameters, the one or more parameters corresponding to one or more pixels of the pixel data;
transmitting, by the data acquisition system, the one or more parameters to a condition monitoring system;
evaluating, by the condition monitoring system, the one or more parameters based on one or more conditions to determine that at least one of the one or more parameters meet at least one of the one or more conditions;
based on the evaluating, determining, by the condition monitoring system, one or more battery maintenance actions based on the at least one of the one or more parameters that meets the at least one of the one or more conditions; and
outputting, by the condition monitoring system, the one or more battery maintenance actions to one or more user interfaces of a user device.

18. The non-transitory computer-readable medium of claim 17, the instructions further comprising:
transmitting, by the data acquisition system, the one or more parameters to a prognostic analytics system;
predicting, by the prognostic analytics system, one or more predicted pixel state values utilizing a machine-learning algorithm based on the one or more parameters and one or more previous pixel states; and
storing, by the prognostic analytics system, the one or more predicted pixel state values in one or more data stores.

19. The non-transitory computer-readable medium of claim 18, the instructions further comprising:
determining, by the prognostic analytics system, one or more battery predictive actions based on the one or more predicted pixel state values; and
outputting, by the condition monitoring system, the one or more battery predictive actions to the one or more user interfaces of the user device.

20. The non-transitory computer-readable medium of claim 17, wherein the at least one battery is a lithium battery.
